(19) United States
(12) Patent Application Publication
(10) Pub. No.: US 2011/0303272 A1
(43) Pub. Date: Dec. 15, 2011

(54) Photoelectric Conversion Device and Manufacturing Method Thereof

(75) Inventors: Kazuo Nishi, Hujisawa (JP); Takashi Hirose, Isehara (JP); Fumito Isaka, Zama (JP); Naoto Kusumoto, Isehara (JP)

(73) Assignee: Semiconductor Energy Laboratory Co., Ltd.

(21) Appl. No.: 13/154,990

(22) Filed: Jun. 7, 2011

(30) Foreign Application Priority Data
Jun. 9, 2010 (JP) 2010-131841

(51) Int. Cl. H01L 31/075; H01L 31/0264

(52) U.S. Cl. 136/255; 438/87; 257/E31.004

(57) ABSTRACT

An object is to provide a photoelectric conversion device in which defects are suppressed as much as possible by filling a separation process region of a semiconductor film with an insulating resin. A photoelectric conversion device includes a first conductive layer formed over a substrate; first to third semiconductor layers formed over the first conductive layer; a second conductive layer formed over the third semiconductor layer; a first separation groove for separating the first conductive layer and the first to third semiconductor layers into a plurality of pieces; a second separation groove for separating the first to third semiconductor layers into a plurality of pieces; and a third separation groove for separating the second conductive layer into a plurality of pieces. An insulating resin is filled in a structural defect that exists in at least one of the first to third semiconductor layers, and in the first separation groove.

### BACKGROUND OF THE INVENTION

1. Field of the Invention

The present invention relates to a photoelectric conversion device and a manufacturing method thereof.

2. Description of the Related Art

In recent years, photoelectric conversion devices that do not produce carbon dioxide during power generation have received attention as a measure against global warming. As a typical example of this, solar batteries for power supply in residential use or the like, which generate power with outside solar light, are known. Such solar batteries are mainly formed using crystalline silicon such as single crystalline silicon or polycrystalline silicon, and although power can be generated efficiently when light with high illuminance such as solar light is emitted, there is a problem that power generation capability drops significantly when the weather is cloudy or raining. Furthermore, the solar batteries pretty much cannot generate power indoors under fluorescent lighting or the like.

On the other hand, there are solar batteries that are known which can generate necessary amounts of power even in a low illuminance environment such as under fluorescent lighting. Typically, there are amorphous silicon solar batteries with high absorption characteristics in a wavelength region of fluorescent lighting, and are used to operate apparatuses with low power consumption such as calculators and wristwatches.

Amorphous silicon solar batteries are thin-film solar batteries, and have an advantage that they can be manufactured at a low cost. However, thin-film solar batteries are structurally weak against tiny defects, and electrical characteristics can be degraded due to structural defects such as pinholes and scratches.

The structural defects cause short circuits and leak currents by their own effects or by affecting another process and reducing parallel resistance between electrodes of a solar battery. Even if a leak current is very small, under low illuminance that generates little electrical current, electrical characteristic of the solar cell becomes extremely degraded.

As a means for solving such problems, Patent Document 1 discloses a method of preventing a short circuit between top and bottom electrodes by applying a photo-resist over a semiconductor film that has a structural defect and prebaking it to fix the photo-resist on the structural defect, and then unfixing unnecessary photo-resist that is over the semiconductor film by ultraviolet light irradiation and removing it by a development process.

### REFERENCE

### Patent Document

[Patent Document 1] Japanese Published Patent Application No. S62-069566

### SUMMARY OF THE INVENTION

Although the above structural defect is formed accidentally in a region that is a photoelectric conversion layer, a structural defect may also be formed in a processing region for integrating a photoelectric conversion device.

Note that in this specification, a “structural defect” refers to a defect where a portion of a film is missing, and does not refer to a crystal defect where a crystal structure is disturbed or the like.

For example, in a region in which a photoelectric conversion layer is processed and separated with a laser, in the case that a residue material, a scattered material, or the like from the process is left behind, or in the case that adhesion between a material that is exposed at a bottom of a separation process region and a film that is formed thereover is poor, a structural defect may occur due to peeling of a film. Furthermore, a wall surface of the separation process region is approximately perpendicular to a substrate, and there are cases in which coverage by a film that is formed in the region is defective. In this case, a defective portion in the coverage becomes a structural defect. Such a structural defect caused by such a phenomenon encourages a short circuit, a leak current, or the like between top and bottom electrodes of the photoelectric conversion device. Consequently, electrical characteristic under low illuminance is degraded.

Accordingly, an object of one embodiment of the present invention is to inactivate a structural defect that is formed in a region that is a photoelectric conversion layer and in a processing region for integration in a photoelectric conversion device, and prevent a short circuit or a leak current between top and bottom electrodes.

One embodiment of the present invention relates to a photoelectric conversion device with a structure of filling with an insulating resin a region of processing and separating a photoelectric conversion layer and a structural defect that is formed undesirably in a semiconductor layer, and a manufacturing method thereof.

One embodiment of the present invention disclosed in this specification is a photoelectric conversion device including a first conductive layer that is formed over a substrate; a first semiconductor layer having one conductivity type that is formed over the first conductive layer; a second semiconductor layer made of an intrinsic semiconductor that is formed over the first semiconductor layer; a third semiconductor layer having an opposite conductivity type to the one conductivity type that is formed over the second semiconductor layer; a second conductive layer that is formed over the third semiconductor layer; a first separation groove that separates the first conductive layer, the first semiconductor layer, the second semiconductor layer, and the third semiconductor layer into a plurality of pieces; a second separation groove that separates the first semiconductor layer, the second semiconductor layer, and the third semiconductor layer into a plurality of pieces; and a third separation groove that separates the second conductive layer into a plurality of pieces, wherein a structural defect that exists in at least one of the first semiconductor layer, the second semiconductor layer, and the third semiconductor layer, and the first separation groove are filled with an insulating resin, and the second conductive layer is formed in the second separation groove.

In this specification, the ordinal numbers such as “first” and “second” are given for convenience to distinguish between elements, and they are not given to limit the number, the arrangement, or the order of the steps.

Another embodiment of the present invention disclosed in this specification is a photoelectric conversion device including a first conductive layer that is formed over a substrate; a first semiconductor layer having one conductivity type that is formed over the first conductive layer; a second semiconductor layer made of an intrinsic semiconductor that is formed over the first semiconductor layer; a third semiconductor layer having an opposite conductivity type to the one conductivity type that is formed over the second semiconductor layer; a second conductive layer that is formed over the third semiconductor layer; a third conductive layer that is formed over the second conductive layer; a first separation groove that separates the first conductive layer, the first semiconductor layer, the second semiconductor layer, and the third semiconductor layer into a plurality of pieces; a second separation groove that separates the second conductive layer into a plurality of pieces; and a connection groove for the third conductive layer to connect to the first conductive layer, wherein a structural defect that exists in at least one of the first semiconductor layer, the second semiconductor layer, and the third semiconductor layer, and the first separation groove are filled with an insulating resin, and the second conductive layer is formed in the second separation groove.

Here, the second semiconductor layer made from the intrinsic semiconductor layer is preferably formed using amorphous silicon.

Also, the insulating resin is preferably a positive-type photosensitive resin.

Another embodiment of the present invention disclosed in this specification is a manufacturing method of a photoelectric conversion device including the steps of forming a first conductive layer over a substrate; forming a first semiconductor layer having one conductivity type over the first conductive layer; forming a second semiconductor layer made of an intrinsic semiconductor over the first semiconductor layer; forming a third semiconductor layer having an opposite conductivity type to the one conductivity type over the second semiconductor layer; forming a first separation groove for separating the first conductive layer, the first semiconductor layer, the second semiconductor layer, and the third semiconductor layer into a plurality of pieces; forming an insulating resin so as to cover the third semiconductor layer and to fill the first separation groove; removing an unnecessary region of the insulating resin; forming the second separation groove for separating the first semiconductor layer, the second semiconductor layer, and the third semiconductor layer into a plurality of pieces; forming a second conductive layer so as to cover the third semiconductor layer and the insulating resin and to fill the second separation groove; and forming a third separation groove for separating the second conductive layer into a plurality of pieces.

Yet another embodiment of the present invention disclosed in this specification is a manufacturing method of a photoelectric conversion device including the steps of forming a first conductive layer over a substrate; forming a first semiconductor layer having one conductivity type over the first conductive layer; forming a second semiconductor layer made of an intrinsic semiconductor over the first semiconductor layer; forming a third semiconductor layer having an opposite conductivity type to the one conductivity type over the second semiconductor layer; forming a first separation groove for separating the first conductive layer, the first semiconductor layer, the second semiconductor layer, and the third semiconductor layer into a plurality of pieces; forming a first insulating resin so as to cover the third semiconductor layer and to fill the first separation groove; removing an unnecessary region of the first insulating resin; forming a second insulating resin into an island shape over the third semiconductor layer; forming a second conductive layer over the third semiconductor layer, the first insulating resin, and the second insulating resin; forming a second separation groove for separating the second conductive layer into a plurality of pieces; forming a third insulating resin into an island shape over the second separation groove; forming a third conductive layer over the second conductive layer; and forming a connection groove for electrically connecting the third conductive layer and the first conductive layer.

Here, the photosensitive resin is also filled in a structural defect that exists in at least one of the first semiconductor layer, the second semiconductor layer, and the third semiconductor layer.

Also, for the above-mentioned insulating resin or the first insulating resin, a positive-type photosensitive resin is preferably used, and for the second insulating resin, a thermo-setting resin is preferably used.

By one embodiment of the present invention, a photoelectric conversion device that can supply stable power even under low illuminance can be provided.

### BRIEF DESCRIPTION OF THE DRAWINGS

In the accompanying drawings:

FIG. 1 is a cross-sectional view illustrating a photoelectric conversion device in which an insulating resin is filled in a separation process region of a cell and in a structural defect;

FIGS. 2A to 2D are process cross-sectional views illustrating a manufacturing method of a photoelectric conversion device;

FIGS. 3A to 3D are process cross-sectional views illustrating a manufacturing method of a photoelectric conversion device;

FIGS. 4A to 4D are process cross-sectional views illustrating a manufacturing method of a photoelectric conversion device;

FIGS. 5A to 5D are process cross-sectional views illustrating a manufacturing method of a photoelectric conversion device;

FIGS. 6A to 6D are process cross-sectional views illustrating a manufacturing method of a photoelectric conversion device; and

FIGS. 7A and 7B are block diagrams illustrating an electronic appliance and a charge and discharge control circuit, respectively.

### DETAILED DESCRIPTION OF THE INVENTION

Hereinafter, embodiments of the present invention will be described in detail with reference to the accompanying drawings. However, the present invention is not limited to the description below, and it is easily understood by those skilled in the art that modes and details disclosed herein can be modified in various ways without departing from the spirit and the scope of the present invention. Therefore, the present invention is not construed as being limited to description of the embodiment. Note that in all drawings used to illustrate the embodiments, portions that are identical or portions having similar functions are denoted by the same reference numerals, and their repetitive description may be omitted.

### Embodiment 1

In this embodiment, a structure and a manufacturing method of a photoelectric conversion device according to one embodiment of the present invention are described.

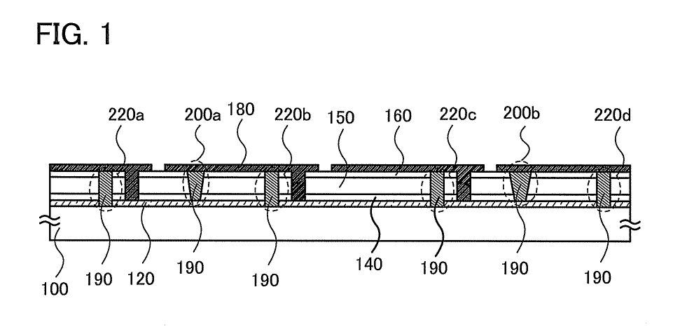

FIG. 1 is a cross-sectional view of a photoelectric conversion device according to one embodiment of the present invention. A photoelectric conversion device in this embodiment has an integrated structure, including a substrate 100, a first electrode 120, a first semiconductor layer 140, a second semiconductor layer 150, a third semiconductor layer 160, a second electrode 180, and an insulating resin 190. Here, an example is shown where cells divided into three are connected in series using the first electrode 120 and the second electrode 180. Needless to say, cells are not limited to three, and a practitioner may appropriately determine the number of divided cells to obtain desired power.

Here, in at least one of the first semiconductor layer 140, the second semiconductor layer 150, and the third semiconductor layer 160, there exist structural defects 200a and 200b which are pinholes, scratches, or the like, and the insulating resin 190 which fill them is formed. By formation of this insulating resin 190, the structural defects 200a and 200b are inactivated, and a short circuit or a leak current between top and bottom electrode layers can be prevented.

Also, the insulating resin 190 is also formed in first separation grooves 220a, 220b, 220c, and 220d which separate the first electrode 120, the first semiconductor layer 140, the second semiconductor layer 150, and the third semiconductor layer 160. Note that a shape of the insulating resin 190 is not limited that that shown in the figure, and any shape is acceptable as long as the insulating resin 190 covers wall surfaces of the structural defects 200a and 200b, and wall surfaces of the first separation grooves 220a, 220b, 220c, and 220d.

In the past, a separation groove for forming the first electrode 120 has been for separating only a conductive film. In this case, due to an effect by a residue material, a scattered material, or the like that remains in the separation groove during the separation process, a semiconductor film that is formed thereover has easily peeled off. Also, in the case that adhesion is weak between a substrate surface that is exposed by the separation process and a semiconductor film that is formed thereover, a similar situation is observed, and a region where film peeling occurred has been a structural defect.

Furthermore, a wall surface of the separation groove that has separated only a conductive film is approximately perpendicular to the substrate, and coverage by a semiconductor film that is formed in that region may become defective. Also, in a top portion of the wall surface, there are cases in which a protrusion that like a burr from metal processing is formed, and coverage defect also occurs easily in such a portion. In such cases, defective portions in the coverage become structural defects.

Note that when forming over a 5-inch-square glass substrate a light-transmitting conductive film, a separation groove that cuts across the light-transmitting conductive film longitudinally, and a semiconductor film thereover, two to six structural defects each with a size of about φ20 μm are formed.

Accordingly, in the one embodiment of the present invention, the first separation grooves 220a, 220b, 220c, and 220d are also formed in the first semiconductor layer 140, the second semiconductor layer 150, and the third semiconductor layer 160 in a manner that is continual from regions that are separated in a light-transmitting conductive film that is the first electrode 120, and then the insulating resin 190 is filled in the separation grooves so that the semiconductor layers are not formed in the separation grooves. With this, insulation between the first electrode 120 and the second electrode 180 is increased, and a short circuit or a leak current can be prevented.

For the substrate 100, a glass plate such as general flat glass, clear flat glass, lead glass, or crystallized glass can be used. Alternatively, a non-alkali glass substrate of aluminosilicate glass, barium borosilicate glass, aluminoborosilicate glass, or the like, or a quartz substrate can be used. In this embodiment, a glass substrate is used as the substrate 100, and this substrate side is set as a light incidence side.

Alternatively, a resin substrate can be used as the substrate 100. For example, the following can be given: polyether sulfone (PES); polyethylene terephthalate (PET);

polyethylene naphthalate (PEN); polycarbonate (PC); a polyamide-based synthetic fiber; polyether etherketone (PEEK); polysulfone (PSF); polyether imide (PEI); polyarylate (PAR); polybutylene terephthalate (PBT); polyimide; an acrylonitrile butadiene styrene resin; poly vinyl chloride; polypropylene; poly vinyl acetate; an acrylic resin, and the like.

As the first electrode 120, a light-transmitting conductive film containing the following can be used: indium tin oxide (ITO); indium tin oxide containing silicon (ITSO); zinc oxide (ZnO); indium tin oxide containing zinc (IZO); zinc oxide containing gallium (GZO); zinc oxide containing aluminum (AZO); tin oxide (SnO₂); tin oxide containing fluorine (FTO); tin oxide containing antimony (ATO); or the like. The above light-transmitting conductive film is not limited to a single layer, and different films may be laminated. For example, a lamination of an ITO film and an AZO film, a lamination of an ITO film and an FTO film, or the like can be used. A film thickness is to be greater than or equal to 100 nm and less than or equal to 1000 nm, preferably greater than or equal to 400 nm and less than or equal to 1000 nm in total. Also, although not shown in the figure, a surface of the first electrode 120 may have a textured structure so as to give a light-trapping effect.

Also, for the second electrode 180, a metal film of aluminum, titanium, nickel, silver, molybdenum, tantalum, tungsten, chromium, copper, stainless steel, or the like can be used. The metal film is not limited to a single layer, and different films may be laminated. For example, a lamination of a stainless steel film and an aluminum film, a lamination of a silver film and an aluminum film, or the like can be used. A total film thickness is to be greater than or equal to 100 nm and less than or equal to 600 nm, preferably greater than or equal to 100 nm and less than or equal to 300 nm. Also, a conductive paste such as a carbon paste, a nickel paste, a silver paste, a molybdenum paste, or a copper paste can be used.

Note that the second electrode 180 may be a lamination of the above light-transmitting conductive film and a metal film. In this case, by having the light-transmitting conductive film on a side that is in contact with a semiconductor layer, reflectivity of light that reaches the second electrode 180 can be improved. Here, the film thickness of the light-transmitting conductive film is preferably greater than or equal to 10 nm and less than or equal to 100 nm. For example, a lamination in which an aluminum film, a silver film, and an ITO film are formed in this order from the substrate side can be used.

Since the substrate 100 side is set as the light incidence side in this embodiment, an ITO film which is a light-transmitting conductive film is used for the first electrode 120, and a lamination of a stainless steel film and an aluminum film is used for the second electrode 180. In the case that the light incidence side is set on the opposite side as the substrate 100 side, materials used for the electrodes may be reversed. Note that although a light-transmitting conductive film is used for an electrode on the light incidence side, a type of an opposing electrode is not limited, and the practitioner may appropriately select the type of electrode to be used.

For the first semiconductor layer 140, a semiconductor film having one conductivity type can be used, and for the third semiconductor layer 160, a semiconductor film having an opposite conductivity type to the one conductivity of the first semiconductor layer 140 can be used. In this embodiment, although a p-type silicon semiconductor film is used for the first semiconductor layer 140 and an n-type silicon semiconductor film is used for the third semiconductor layer 160, conductivity types may be reversed. Note that the film thickness of the first semiconductor layer 140 is preferably greater than or equal to 5 nm and less than or equal to 30 nm, and the film thickness of the third semiconductor layer 160 is preferably greater than or equal to 10 nm and less than or equal to 30 nm. Furthermore, although amorphous silicon can be used for the first semiconductor layer 140 and the third semiconductor layer 160, microcrystalline silicon or polycrystalline silicon that has lower resistance is preferably used.

For the second semiconductor layer 150, an intrinsic semiconductor is used. Note that in this specification, an “intrinsic semiconductor” refers not only to a so-called intrinsic semiconductor in which the Fermi level lies in the middle of a band gap, but also to a semiconductor in which a concentration of an impurity imparting p-type or n-type conductivity is 1×10²⁰ cm⁻³ or lower, and in which photoconductivity is 100 times or more than a dark conductivity. This intrinsic semiconductor may include an impurity element belonging to Group 13 or Group 15 of the periodic table. Note that the film thickness of the second semiconductor layer 150 is preferably greater than or equal to 100 nm and less than or equal to 600 nm.

As the intrinsic semiconductor used for the second semiconductor layer 150, amorphous silicon, microcrystalline silicon, polycrystalline silicon, or the like can be used. In the case of use in a low illuminance environment such as under fluorescent lighting, it is preferable to use amorphous silicon which has high photoelectric conversion capability with respect to visible light ray.

As the insulating resin 190 which fills the first separation groove and the structural defects 200a and 200b formed in the region including the first semiconductor layer 140, the second semiconductor layer 150, and the third semiconductor layer 160, a photosensitive resin is used.

Here, the structural defects 200a and 200b are pinholes that are formed undesirably due to a particle or the like during a process for forming the semiconductor layers. Note that in FIG. 1, although the structural defects 200a and 200b are shown in a manner that penetrates the three semiconductor layers of the first semiconductor layer 140, the second semiconductor layer 150, and the third semiconductor layer 160, a process of structural defect formation results from various phenomenons, and is not limited thereto. For example, there is a case in which a structural defect is formed above the second semiconductor layer 150, or a case in which a structural defect is formed in a manner that includes the first electrode 120. In either case, a structural defect is a region in which a layer that is supposed to be formed is missing, and a possibility of another layer getting in to that region is high. Accordingly, this becomes a cause for degradation of an electrical characteristic such as a short circuit or a leak current.

Note that a scratch formed on a film surface is also a structural defect, and becomes a cause for malfunction in the same manner as a pinhole. A scratch on a film surface is formed mainly by contact with another object.

Next, a manufacturing method of a photoelectric conversion device according to an embodiment of the present invention will be described in detail. Note that here, as an example of a structural defect, a case in which a pinhole is formed will be described.

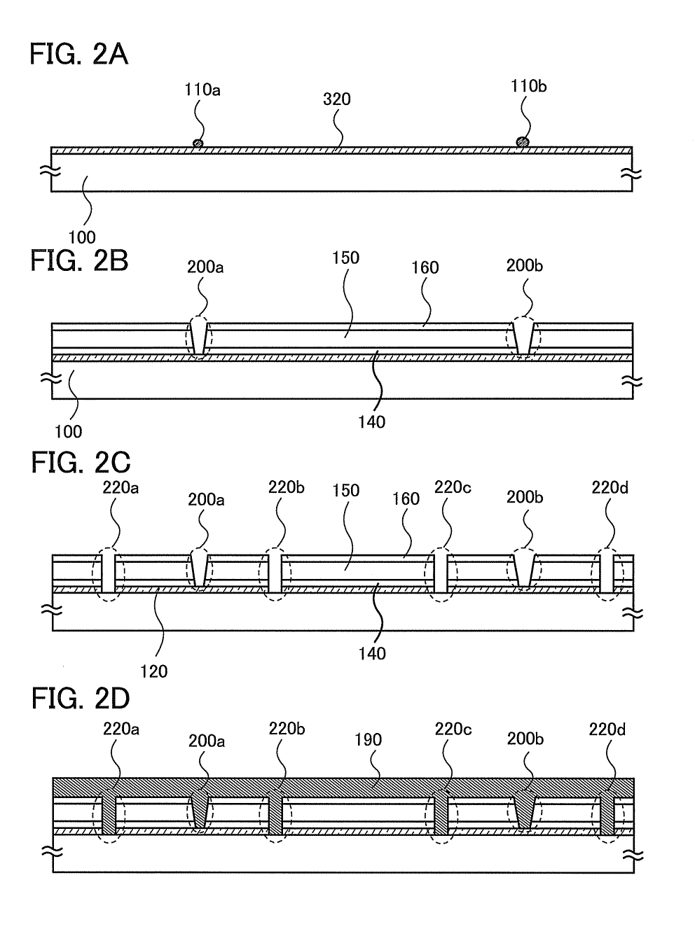

First, a light-transmitting conductive film 320 serving as the first electrode 120 is formed over the substrate 100 which is a glass substrate or the like. Here, by a sputtering method, an ITO film is formed with a thickness of 500 nm. At this time, particles 110a and 110b are attached accidentally to the light-transmitting conductive film 320 (see FIG. 2A).

Next, as the first semiconductor layer 140, a p-type microcrystalline silicon film is formed with a thickness of 30 nm. In this embodiment, a doping gas containing an impurity imparting p-type conductivity is mixed into a source gas, and a p-type microcrystalline silicon film is formed by a plasma CVD method. As the impurity imparting p-type conductivity, boron, aluminum, or the like that is a Group 13 element in the periodic table can be given. For example, a doping gas such as diborane is mixed into a source gas such as silane and used in forming a p-type microcrystalline silicon. Note that although the first semiconductor layer 140 may be formed using amorphous silicon, it is preferably formed using microcrystalline silicon which has lower resistance and favorable adhesion to the light-transmitting conductive film 320.

Next, by a plasma CVD method, an i-type amorphous silicon film is formed with a thickness of 600 nm as the second semiconductor layer 150. As a source gas, silane or disilane can be used, and hydrogen may be added thereto. At this time, an atmospheric component contained in the film may serve as a donor in some cases; therefore, greater than or equal to 0.001 at. % and less than or equal to 0.1 at. % of boron (B) may be added to the film so that the conductivity type may become close to i-type.

Furthermore, by a plasma CVD method, an n-type microcrystalline film with a thickness of 30 nm is formed as the third semiconductor layer 160. The n-type microcrystalline silicon is formed using a source gas into which a doping gas containing an impurity imparting n-type conductivity is mixed. As the impurity imparting n-type conductivity, phosphorus, arsenic, or antimony which is a Group 15 element in the periodic table, or the like can be typically given. For example, a doping gas such as phosphine is mixed into a source gas such as silane, and used in forming the n-type microcrystalline silicon film. Note that although the third semiconductor layer 160 may be formed using amorphous silicon, it is preferably formed using microcrystalline silicon which has lower resistance.

Here, the particles 110a and 110b attached to the light-transmitting conductive film 320 form the structural defects 200a and 200b in the first semiconductor layer 140, the second semiconductor layer 150, and the third semiconductor layer 160 (see FIG. 2B). Note that FIG. 2B shows a state in which the particles and the semiconductor layers formed thereover are removed.

Next, the first separation grooves 220a, 220b, 220c, and 220d are formed, which separate the light-transmitting conductive film 320, the first semiconductor layer 140, the second semiconductor layer 150, and the third semiconductor layer 160 into a plurality of pieces (see FIG. 2C). The separation grooves can be formed by a laser process or the like. A laser used in this laser process is preferably a continuous wave laser or a pulsed laser which emits light in an infrared light region. For example, the laser process may be performed using an Nd-YAG laser (wavelength of 1064 nm) with a beam diameter of 30 μm, an output of 0.5 W, an oscillation frequency of 25 kHz, and a scanning speed of 20 cm/sec. Note that here, a portion of the separation grooves may reach the substrate 100. Also, by the light-transmitting conductive film 320 getting separated in this step, the first electrode 120 is formed.

In this manner, by processing the light-transmitting conductive film and the semiconductor layers in a laminated state, the number of steps can be reduced, and particles that are generated during the laser process can also be reduced.

Alternatively, the light-transmitting conductive film and the semiconductor layers may be separated separately. In this case, the light-transmitting conductive film 320 is formed, the laser process is performed to form the first separation grooves, the first semiconductor layer 140, the second semiconductor layer 150, and the third semiconductor layer 160 are formed thereover, and then the laser process is performed again on the semiconductor layers in which the first separation grooves are formed. By performing such steps, a form similar to one shown in FIG. 2C can be obtained.

Note that a step of forming the first separation grooves 220a, 220b, 220c, and 220d needs to be after forming the semiconductor layers. If the step of forming the separation grooves is performed after forming the conductive layer over the semiconductor layers, the conductive layer is formed in the structural defects 200a and 200b, and this leads to malfunction such as a short circuit or a leak current.

Next, the insulating resin 190 is formed in a manner that covers the third semiconductor layer 160 and fills the structural defects 200a and 200b, and the first separation grooves 220a, 220b, 220c, and 220d (see FIG. 2D). A photosensitive resin is used as the insulating resin. For example, there is a photo-resist, photosensitive polyimide, or the like, and by exposing a portion thereof, a desired form can be obtained.

In this embodiment, a photo-resist is used. There is a positive-type and a negative-type photo-resist, and either can be used. The photo-resist is formed with a thickness of greater than or equal to 0.5 μm and less than or equal to 5 μm using a spin-coater or a slit-coater, and after prebaking it, exposure is performed using light with a wavelength with which the photo-resist to be used is exposed. For example, ultraviolet light with a wavelength of greater than or equal to 300 nm and less than or equal to 400 nm can be used.

In the case of a positive-type photo-resist, exposure is performed from a photo-resist side, and exposure time is adjusted so that the photo-resist up to a surface of the third semiconductor layer is exposed. In this case, a portion that is not exposed becomes fixed, and a portion that is exposed becomes unfixed. In the case of a negative-type photo-resist, exposure is performed from a substrate side. Exposure can be performed on regions of the structural defects and separation grooves through a light-transmitting substrate or a light-transmitting conductive film. In this case, a portion that is exposed becomes fixed, and a portion that is not exposed becomes unfixed.

Note that in the case of using a negative-type photosensitive resin, the first electrode 120 needs to be a light-transmitting conductive film. If a metal film is used for the first electrode 120, light is blocked in all portions except the first separation grooves 220a, 220b, 220c, and 220d, and the photosensitive resin that is filled in the structural defects 200a and 200b cannot be exposed. Also, in the case where a structural defect is formed only in a top layer of the semiconductor layers, light is blocked by the semiconductor layer in a lower layer, and the photosensitive resin cannot be exposed. Furthermore, since exposure is performed from the substrate 100 side, the semiconductor layers are irradiated with ultraviolet light through a light-transmitting conductive film which is the first electrode 120. In this embodiment, since amorphous silicon is used for the second semiconductor layer 150, irradiation of ultraviolet light encourages light degradation, which is not preferable. Accordingly, the photosensitive resin used as the insulating resin 190 is preferably a positive type.

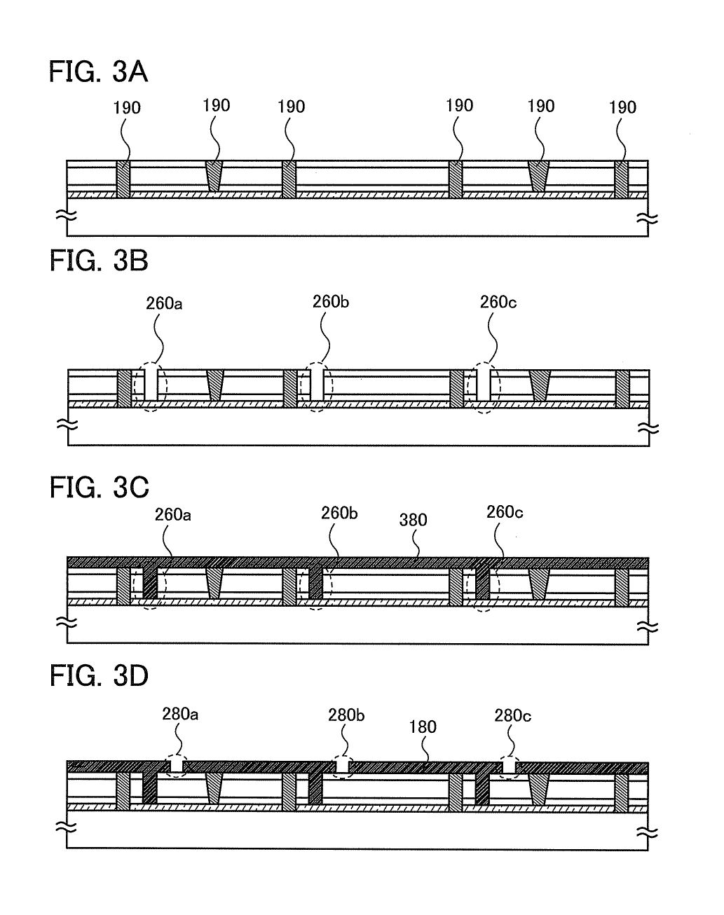

Next, by developing with a developing solution, the unfixed photo-resist can be removed while leaving behind the photo-resist (insulating resin 190) that is fixed in the structural defects 200a and 200b, and the first separation grooves 220a, 220b, 220c, and 220d (see FIG. 3A). Then, post baking is performed, and the photo-resist is chemically stabilized.

Next, second separation grooves 260a, 260b, and 260c are formed, which separate the first semiconductor layer 140, the second semiconductor layer 150, and the third semiconductor layer 160 into a plurality of pieces (see FIG. 3B). The separation grooves can be formed by a laser process or the like. A laser used in this laser process is preferably a continuous wave laser or a pulsed laser which emits light in a visible light region or an infrared light region. For example, the laser process may be performed using the second harmonic of an Nd-YAG laser (wavelength of 532 nm) with a beam diameter of 30 μm, an output of 0.05 W, an oscillation frequency of 20 kHz, and a stage scanning speed of 50 cm/sec.

Next, a conductive film 380 serving as the second electrode 180 is formed. Here, a lamination of a stainless steel film with a thickness of 5 nm and an aluminum film with a thickness of 300 nm is used. Note that the stainless steel film is to be on a side that comes into contact with the third semiconductor layer 160 (see FIG. 3C).

Then, third separation grooves 280a, 280b, and 280c are formed, which separate the conductive film 380 into a plurality of pieces (see FIG. 3D). The separation grooves can be formed by a laser process or the like. A laser used in this laser process is preferably a continuous wave laser or a pulsed laser which emits light in a visible light region or an infrared light region. For example, the laser process may be performed using a second high frequency wave of an Nd-YAG laser (wavelength of 532 nm) with a beam diameter of 30 μm, output of 0.05 W, an oscillation frequency of 20 kHz, and a stage scanning speed of 50 cm/sec. Note that by the conductive film 380 getting separated in this step, the second electrode 180 is formed.

Here, the semiconductor layers in a region that is irradiated by the laser during the laser process may be removed.

Note that the second electrode 180 may be formed by screen printing. In this case, a conductive paste such as a carbon paste, a nickel paste, a silver paste, or a molybdenum paste can be used. Furthermore, since a desired form can be directly formed by screen printing, the third separation grooves 280a, 280b, and 280c are formed without the laser process described above.

Note that although not shown in the figure, a protective insulating layer for improving reliability may be formed in a manner that covers the second electrode 180 and fills the third separation grooves 280a, 280b, and 280c, while excluding a terminal portion (a portion of the second electrode 180) for taking out power to the exterior. For the protective insulating layer, an inorganic film or an insulating resin can be used.

By the above steps, a photoelectric conversion device with little structural defect that can generate power stably even under low illumination can be manufactured.

This embodiment can be implemented in appropriate combination with a structure described in another embodiment.

### Embodiment 2

In this embodiment, a photoelectric conversion device that is different from that described in Embodiment 1, and a manufacturing method thereof will be described.

Note that in this embodiment, unlike the example described in Embodiment 1, an example is described in which the opposite side of the substrate side is the light incidence side. As a material that can be used in a structure of the photoelectric conversion device described in this embodiment, the same material used for the photoelectric conversion device described in Embodiment 1 can be used. Furthermore, although description is made using a pinhole as an example of a structural defect in this embodiment also, a scratch is handled in the same manner.

First, the conductive film 380 serving as a first electrode 420 is formed over the substrate 100. Here, a polyethylene naphthalate (PEN) substrate of a resin material is used as the substrate 100. Although the thickness of the substrate 100 is not limited, roll-to-roll processing can be performed if a thin substrate with a thickness of about 100 μm is used, for example.

In roll-to-roll processing, in addition to a film formation step by a sputtering method, a plasma CVD method, or the like, a step by a screen printing method, a laser processing method, or the like is included. Accordingly, almost the entire manufacturing process of a photoelectric conversion device can be performed by roll-to-roll processing. Furthermore, the process may partially be performed by roll-to-roll processing, and then divided into sheet forms to perform latter steps individually for each sheet. For example, by attaching each piece of the divided sheet to a frame that is formed of ceramic, a metal, a composite body thereof, or the like, it can be handled in the same manner as a glass substrate or the like.

The conductive film 380 is formed by a sputtering method. For the conductive film 380, the same material used for the second electrode 180 described in Embodiment 1 can be used. Here, as the conductive film 380, a metal film is used in which an aluminum film with a thickness of 300 tun and a stainless steel film with a thickness of 5 nm are laminated in this order from the substrate 100 side.

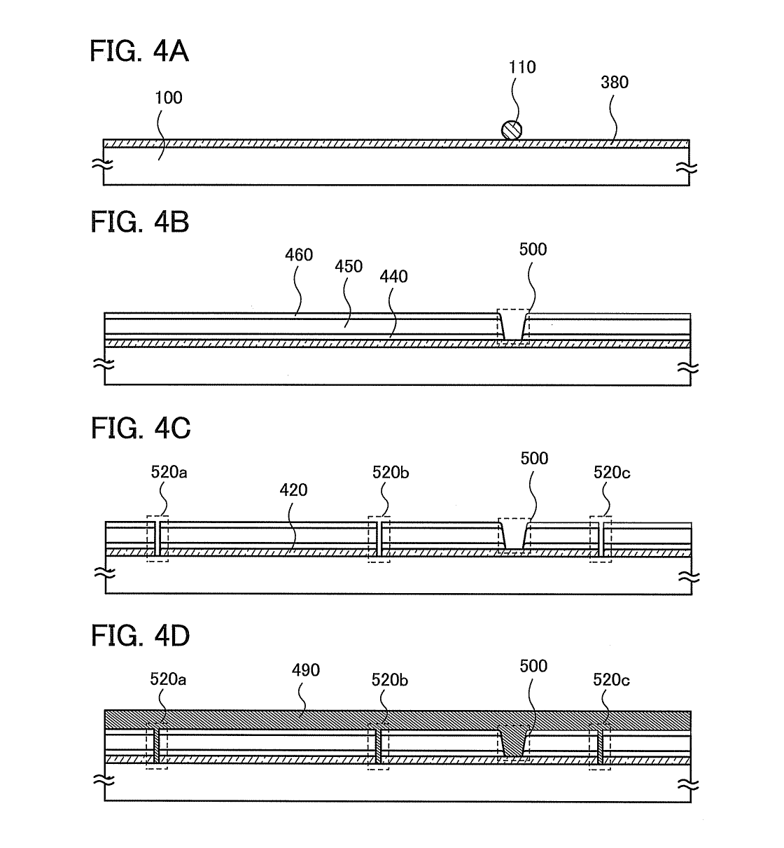

Hereinafter, an example in which a particle 110 is attached undesirably to the conductive film 380 after forming the conductive film 380 is described (see FIG. 4A). Although the particle 110 is shown to have a spherical shape in the figure as an example, there are various modes in size, shape, and material.

Next, by a plasma CVD method, an n-type microcrystalline silicon film with a thickness of 30 nm is formed as a first semiconductor layer 440; an i-type amorphous silicon film with a thickness of 600 nm is formed as a second semiconductor layer 450; and a p-type microcrystalline silicon with a thickness of 30 nm is formed as a third semiconductor layer 460, in this order. Here, a structural defect 500 is formed due to the particle 110 being in the way.

The particle 110 is unstably attached to the first electrode 420; therefore, it may be moved by a small vibration, air current, or the like. Also, the particle 110 may be intentionally removed by a cleaning step. Such a state is shown in FIG. 4B.

Next, first separation grooves 520a, 520b, and 520c are formed, which separate the conductive film 380, the first semiconductor layer 440, the second semiconductor layer 450, and the third semiconductor layer 460 into a plurality of pieces (see FIG. 4C). The separation grooves can be formed by the laser processing method used to form the first separation grooves 220a, 220b, 220c, and 220d in Embodiment 1. Note that here, a portion of the separation grooves may reach the substrate 100. Furthermore, by the conductive film 380 getting separated in this step, the first electrode 420 is formed.

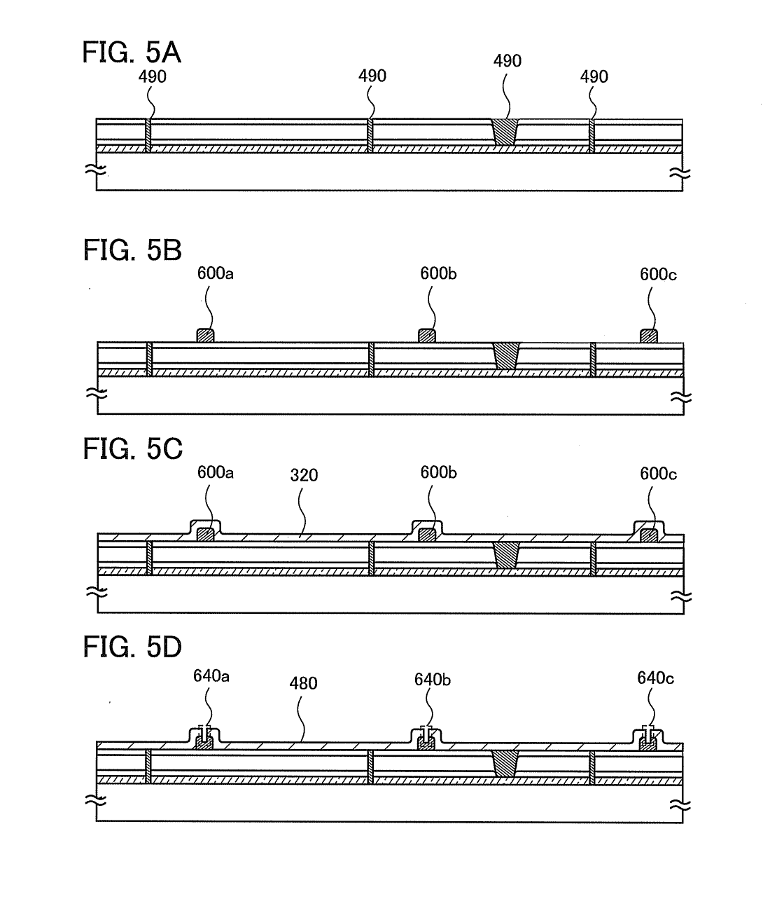

Next, a first insulating resin 490 is formed in a manner that covers the third semiconductor layer 460 and fills the structural defect 500 and the first separation grooves 520a, 520b, and 520c (see FIG. 4D). As the first insulating resin 490, the insulating resin 190 described in Embodiment 1 can be used. In this embodiment, in the same manner as in Embodiment 1, a photo-resist is formed and then exposure and development is performed to remove unnecessary photo-resist. Then, by performing post baking, a photo-resist (the first insulating resin 490) that is filled in the structural defect 500 and the first separation grooves 520a, 520b, and 520c is stabilized (see FIG. 5A).

Next, second insulating resins 600a, 600b, and 600c are formed over the third semiconductor layer 460 (see FIG. 5B). The second insulating resins 600a, 600b, and 600c serve as stoppers when performing a laser process on a light-transmitting conductive film that is formed thereover.

The insulating resins are preferably formed by a screen printing method, and a thermo-setting resin such as an epoxy resin, a phenol resin, a silicone resin, an acrylic resin, or a polyimide resin can be used. In this embodiment, an epoxy resin is used. Also, the resin preferably has a black color in order to encourage absorption of the above-mentioned laser light.

Next, the light-transmitting conductive film 320 is formed over the third semiconductor layer 460, the first insulating resin 490, and the second insulating resins 600a, 600b, and 600c, by a sputtering method (see FIG. 5C). For the light-transmitting conductive film 320, the same material used for the first electrode 120 in Embodiment 1 can be used. Here, an ITO film with a thickness of 100 nm is used.

Next, portions where the second insulating resins 600a, 600b, and 600c are stacked over the light-transmitting conductive film 320 are subjected to a laser process, to form second separation grooves 640a, 640b, and 640c (see FIG. 5D). The separation grooves can be formed by the laser processing method that is used to form the first separation grooves 220a, 220b, 220c, and 220d in Embodiment 1. Note that here, a groove many formed in a portion of each of the second insulating resins 600a, 600b, and 600c. Furthermore, by the light-transmitting conductive film 320 getting separated in this step, a second electrode 480 is formed.

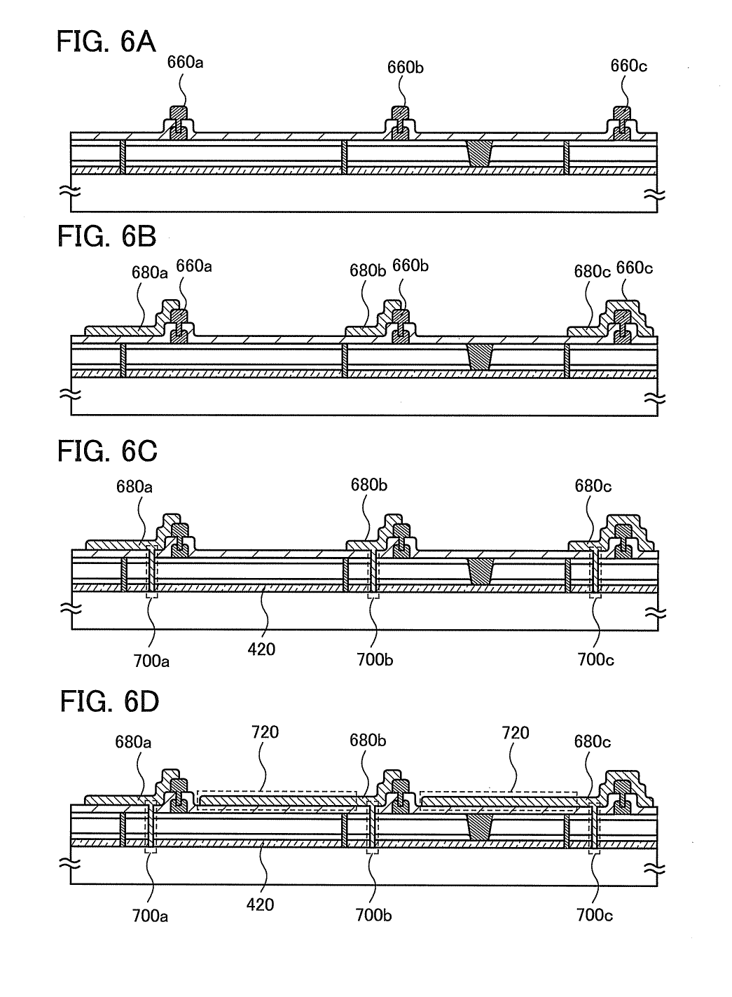

Next, third insulating resins 660a, 660b, and 660c are formed for sealing the second separation grooves 640a, 640b, and 640c (see FIG. 6A). The insulating resins can be formed using the same method and material that are used to form the second insulating resins 600a, 600b, and 600c.

Next, third electrodes 680a, 680b, and 680c are formed so as to be in contact with the second electrode 480 (see FIG. 6B). The third electrodes 680a, 680b, and 680c can be formed by a screen printing method. A thermo-setting conductive paste is preferably used for a material, such as a silver paste, for example.

Then, laser light is emitted from above the third electrodes 680a, 680b, and 680c, to form connection grooves 700a, 700b, and 700c (see FIG. 6C). The connection grooves are regions that weld together and electrically connect the third electrode 680a, 680b, and 680c to the first electrode 420. Note that the connection grooves may be formed by forming separation grooves in the first electrode 420, the first semiconductor layer 440, the second semiconductor layer 450, and the third semiconductor layer 460, and then filling the separation grooves to form the third electrodes 680a, 680b, and 680c.

Here, the third electrode 680a serves as a extraction electrode for taking out the first electrode 420 of an adjacent cell to a surface side. Also, the third electrode 680b serves as a connection electrode for connecting adjacent cells in series. Furthermore, the third electrode 680c serves as a extraction electrode of the second electrode 480 to which the electrode is connected. Here, although the third electrode 680c can serve as the extraction electrode even without forming the connection groove 700c, since resistance can be lowered by a portion of the third electrode 680c being connected to the first electrode 420, it is preferable to form the connection groove 700c. Note that in this embodiment, although an example of an integration process in which two cells are connected in series is described, the number of cells to be integrated is not limited thereto, and can be appropriately determined by the practitioner.

Also, as shown in FIG. 6D, a grid electrode 720 may be formed, which extends from a portion of each of the third electrode 680b and the third electrode 680c towards an adjacent cell. By forming the grid electrode 720, resistance loss can be reduced, and electrical characteristic can be improved particularly under high illuminance. Note that the grid electrodes 720 are formed with space therebetween and toward a depth direction of the figure; therefore, they do not cover an entire light-receiving surface. FIG. 6D shows a cross-sectional view of a region where the grid electrodes 720 are formed.

Also, although not shown in the figure, as a sealing resin for improving reliability, a light-transmitting insulating resin may be provided on a light-receiving surface side. The sealing resin can be formed by a screen printing method using a thermo-setting epoxy resin, phenol resin, or the like.

By the above process, an integrated photoelectric conversion device with high yield can be manufactured, in which a defect such as a short circuit or a leak current can be suppressed as much as possible.

This embodiment can be implemented in appropriate combination with the structures described in the other embodiments.

### Embodiment 3

A photoelectric conversion device disclosed in this specification can be used in various electronic devices. In this embodiment, an example of using the photoelectric conversion device as a power source of an electronic book will be described.

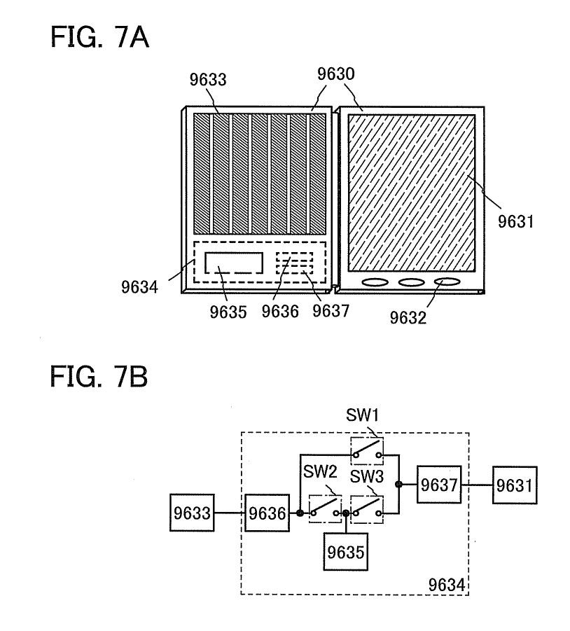

FIG. 7A shows an electronic book (also called an “E-book”), which can include a housing 9630, a display portion 9631, an operation key 9632, a photoelectric conversion device 9633, and a charge and discharge control circuit 9634. The electronic book shown in FIG. 7A can have a function of displaying various data (such as a still image, a moving image, and a text image), a function of displaying a calendar, a date, a time, or the like on the display portion, a function of operating or editing the data displayed on the display portion, a function of controlling processing by various software (programs), and the like. Note that FIG. 7A shows an example of a structure of the charge and discharge control circuit 9634 that includes a battery 9635, a DCDC converter 9636, and a DCDC converter 9637. By using the photoelectric conversion device described in the other embodiment as the photoelectric conversion device 9633, power can be generated efficiently even under low illumination; therefore, an electronic book which does not require a commercial power source even indoors can be manufactured.

By using a semi-transmissive-type or reflective-type liquid crystal display device for the display portion 9631 of the electronic book shown in FIG. 7A, power consumption can be suppressed. Note that the photoelectric conversion device 9633 is not limited to a region shown in the figure, and can be appropriately provided in an empty space (a front surface or a rear surface) of the housing 9630. Note that as the battery 9635, there is an advantage in using a lithium ion battery in that size reduction or the like can be realized.

Furthermore, a structure and an operation of the charge and discharge control circuit 9634 shown in FIG. 7A will be described with reference to a block diagram in FIG. 7B. FIG. 7B shows the photoelectric conversion device 9633, the charge and discharge control circuit 9634, and the display portion 9631. Here, the charge and discharge control circuit 9634 includes the battery 9635, the DCDC converter 9636, the DCDC converter 9637, and switches SW1 to SW3.

First, an example of operation when power is generated by the photoelectric conversion device 9633 with external light will be described. A voltage of power that is generated by the photoelectric conversion device is raised or lowered in the DCDC converter 9636 so as to be a favorable voltage for charging the battery 9635. Then, when performing a display in the display portion 9631, the switch SW1 is turned on, the voltage of the power is raised or lowered in the DCDC converter 9637 to a voltage that is needed in the display portion 9631, and power is supplied to the display portion 9631. On the other hand, when a display is not performed in the display portion 9631, the SW1 is turned off and the SW2 is turned on to charge the battery 9635.

Next, an example of operation when power is not generated by the photoelectric conversion device 9633 due to poor external light will be described. By turning on the switch SW3, a voltage of power that is stored in the battery 9635 is raised or lowered by the DCDC converter 9637 to a voltage that is needed in the display portion 9631, and then supplied to the display portion 9631.

Note that in this embodiment, although two DCDC converters are provided between the photoelectric conversion device and the display portion, the DCDC converters therebetween may be omitted in a structure that allows directly supplying power to the display portion from the photoelectric conversion device, directly charging the battery from the photoelectric conversion device, or directly supplying power to the display portion from the battery.

Note that although an example of only using the photoelectric conversion device 9633 is described as one example of a power generation means, the battery 9635 may be charged by a combination of the photoelectric conversion device 9633 and a photoelectric conversion device with a different structure than the structure of the photoelectric conversion device 9633. Furthermore, the combination may be of the photoelectric conversion device 9633 and another power generation means.

This embodiment can be implemented in appropriate combination with the structures described in the other embodiments.

This application is based on Japanese Patent Application serial no. 2010-131841 filed with Japan Patent Office on Jun. 9, 2010, the entire contents of which are hereby incorporated by reference.

What is claimed is:

1. A photoelectric conversion device comprising:
a first conductive layer over a substrate;
a first semiconductor layer having one conductivity type over the first conductive layer;
a second semiconductor layer over the first semiconductor layer;
a third semiconductor layer having an opposite conductivity type to the first semiconductor layer over the second semiconductor layer;
second conductive layers over the third semiconductor layer, each of the second conductive layers passing through the first semiconductor layer, the second semiconductor layer, and the third semiconductor layer; and
insulating resin portions passing through the first conductive layer, the first semiconductor layer, the second semiconductor layer, and the third semiconductor layer;
wherein a structural defect exists in at least one of the first semiconductor layer, the second semiconductor layer, and the third semiconductor layer,
wherein the structural defect is filled with an insulating resin, and
wherein a material of the insulating resin portions is same as the insulating resin.

2. The photoelectric conversion device according to claim 1, wherein the second semiconductor layer is formed using any one of amorphous silicon, single crystalline silicon, and polycrystalline silicon.

3. The photoelectric conversion device according to claim 1, wherein the second semiconductor layer is an intrinsic semiconductor.

4. The photoelectric conversion device according to claim 1, wherein each of the first semiconductor layer and the third semiconductor layer is formed using microcrystalline silicon or polycrystalline silicon.

5. The photoelectric conversion device according to claim 1, wherein each of the first insulating resins and the second insulating resin is a positive-type photosensitive resin.

6. A photoelectric conversion device comprising:
a first conductive layer over a substrate;
a first semiconductor layer having one conductivity type over the first conductive layer;
a second semiconductor layer over the first semiconductor layer;
a third semiconductor layer having an opposite conductivity type to the first semiconductor layer over the second semiconductor layer;
second conductive layers over the third semiconductor layer;
third conductive layers over the second conductive layers, each of the third conductive layers passing through the first conductive layer, the first semiconductor layer, the second semiconductor layer, the third semiconductor layer, the second conductive layer; and
insulating resin portions passing through the first conductive layer, the first semiconductor layer, the second semiconductor layer, and the third semiconductor layer,
wherein a structural defect exists in at least one of the first semiconductor layer, the second semiconductor layer, and the third semiconductor layer,
wherein the structural defect is filled with an insulating resin, and
wherein a material of the insulating resin portions is same as a material of the insulating resin.

7. The photoelectric conversion device according to claim 6, wherein the second semiconductor layer is formed using any one of amorphous silicon, single crystalline silicon, and polycrystalline silicon.

8. The photoelectric conversion device according to claim 6, wherein the second semiconductor layer is an intrinsic semiconductor.

9. The photoelectric conversion device according to claim 6, wherein each of the first semiconductor layer and the third semiconductor layer is formed using microcrystalline silicon or polycrystalline silicon.

10. The photoelectric conversion device according to claim 6, wherein each of the first insulating resins and the second insulating resin is a positive-type photosensitive resin.

11. A manufacturing method of a photoelectric conversion device comprising the steps of:
forming a first conductive layer over a substrate;
forming a first semiconductor layer having one conductivity type over the first conductive layer;
forming a second semiconductor layer over the first semiconductor layer;
forming a third semiconductor layer having an opposite conductivity type to the first semiconductor layer over the second semiconductor layer;
forming a first separation groove passing through the first conductive layer, the first semiconductor layer, the second semiconductor layer, and the third semiconductor layer;
filling the first separation groove with an insulating resin;
forming a second separation groove passing through the first semiconductor layer, the second semiconductor layer, and the third semiconductor layer;
forming a second conductive layer in the second separation groove, and over the third semiconductor layer and the insulating resin; and
forming a third separation groove for separating the second conductive layer.

12. The manufacturing method of the photoelectric conversion device according to claim 11, wherein the insulating resin is filled in a structural defect that exists in at least one of the first semiconductor layer, the second semiconductor layer, and the third semiconductor layer.

13. The manufacturing method of the photoelectric conversion device according to claim 11, wherein the second semiconductor layer is formed using any one of amorphous silicon, single crystalline silicon, and polycrystalline silicon.

14. The manufacturing method of the photoelectric conversion device according to claim 11, wherein the second semiconductor layer is an intrinsic semiconductor.

15. The manufacturing method of the photoelectric conversion device according to claim 11, wherein each of the first semiconductor layer and the third semiconductor layer is formed using microcrystalline silicon or polycrystalline silicon.

16. The manufacturing method of the photoelectric conversion device according to claim 11, wherein the insulating resin is a positive-type photosensitive resin.

17. The manufacturing method of the photoelectric conversion device according to claim 11, wherein at least one of the first separation groove, the second separation groove, and the third separation groove is formed by a laser process.

18. A manufacturing method of a photoelectric conversion device comprising the steps of:
forming a first conductive layer over a substrate;
forming a first semiconductor layer having one conductivity type over the first conductive layer;
forming a second semiconductor layer over the first semiconductor layer;
forming a third semiconductor layer having an opposite conductivity type to the first semiconductor layer over the second semiconductor layer;
forming a first separation groove passing through the first conductive layer, the first semiconductor layer, the second semiconductor layer, and the third semiconductor layer;
filling the first separation groove with a first insulating resin;
forming a second insulating resin into an island shape over the third semiconductor layer;
forming a second conductive layer over the third semiconductor layer, the first insulating resin, and the second insulating resin;
forming a second separation groove for separating the second conductive layer;
forming a third insulating resin into an island shape over and in contact with the second separation groove;
forming a third conductive layer over the second conductive layer; and
forming a connection groove for electrically connecting the third conductive layer with the first conductive layer.

19. The manufacturing method of the photoelectric conversion device according to claim 18, wherein the first insulating resin is filled in a structural defect that exists in at least one of the first semiconductor layer, the second semiconductor layer, and the third semiconductor layer.

20. The manufacturing method of the photoelectric conversion device according to claim 18, wherein the second semiconductor layer is formed using any one of amorphous silicon, single crystalline silicon, and polycrystalline silicon.

21. The manufacturing method of the photoelectric conversion device according to claim 18, wherein the second semiconductor layer is an intrinsic semiconductor.

22. The manufacturing method of the photoelectric conversion device according to claim 18, wherein each of the first semiconductor layer and the third semiconductor layer is formed using microcrystalline silicon or polycrystalline silicon.

23. The manufacturing method of the photoelectric conversion device according to claim 18, wherein the first insulating resin is a positive-type photosensitive resin.

24. The manufacturing method of the photoelectric conversion device according to claim 18, wherein the second insulating resin and the third insulating resin are each a thermo-setting resin.

25. The manufacturing method of the photoelectric conversion device according to claim 18, wherein at least one of the first separation groove, the second separation groove, and the connection groove is formed by a laser process.
